(19) United States
(12) Patent Application Publication
(10) Pub. No.: US 2022/0069182 A1
(43) Pub. Date: Mar. 3, 2022

(54) IMAGE DISPLAY ELEMENT

(71) Applicant: Sharp Fukuyama Semiconductor Co., Ltd., Fukuyama City (JP)

(72) Inventors: Katsuji IGUCHI, Fukuyama City (JP); Hidenori KAWANISHI, Fukuyama City (JP)

(21) Appl. No.: 17/408,963

(22) Filed: Aug. 23, 2021

(30) Foreign Application Priority Data
Aug. 25, 2020 (JP) 2020-141987

(51) Int. Cl. H01L 33/60; G09G 3/32; H01L 27/15; H01L 33/32; H01L 33/50

(52) U.S. Cl. CPC H01L 33/60; G09G 3/32; H01L 33/505; H01L 33/32; H01L 27/156

(57) ABSTRACT

An image display element includes: pixels arranged in an array, each of the pixels including a micro light emitting element; and a driving circuit substrate including a driving circuit configured to supply a current to the micro light emitting element to cause the micro light emitting element to emit light. The micro light emitting element emits emission light in an opposite direction to the driving circuit substrate. The micro light emitting element includes a light emitting portion configured to generate the emission light, a reflection/transmission film provided on the light emitting portion at a part facing in a light emission direction, and a reflective surface provided on the light emitting portion at a part proximate to the driving circuit substrate. The reflection/transmission film and the reflective surface constitute a microcavity for the emission light. A tilted reflective surface is provided on a side of the light emitting portion.

### CROSS-REFERENCE TO RELATED APPLICATION

The present application claims priority from Japanese Patent Application Number 2020-141987, the content to which is hereby incorporated by reference into this application.

### BACKGROUND OF THE INVENTION

### 1. Field of the Invention

An aspect of the present disclosure relates to an image display element, and more particularly relates to an image display element including a micro light emitting element.

### 2. Description of the Related Art

An image display element including a plurality of micro light emitting elements constituting pixels and disposed on a substrate (backplane) has been proposed. For example, in the technique disclosed in JP 2002-141492 A, a driving circuit is formed on a silicon substrate, and an array of minute light emitting diodes (LED) configured to emit ultraviolet light is disposed on the driving circuit. Additionally, the above literature discloses a micro display element configured to display a color image by providing, on the array of the light emitting diodes, a wavelength conversion layer configured to convert ultraviolet light to red, green, and blue visible light. As another form, a method of performing full color display by using monochrome display elements obtained by stacking compound semiconductors that emit blue, green, and red light on the driving circuit has been proposed.

Such a micro display element is an image display element having a small size and has characteristics of high luminance, and high durability in spite of its small size. Thus, such micro display elements are expected to be display elements such as glasses-like devices, Head-Up Displays (HUDs) or the like.

On the other hand, in light emitting elements and the like, a microcavity structure has been proposed (see U.S. Pat. No. 5,469,018) for the purpose of narrowing a light emission wavelength band, performing light distribution control so that intense radiation is generated forward, or the like. The microcavity structure is provided with a semi-reflective transflective layer on a light emitting surface of a light emitting portion, and includes a reflective layer on an opposite surface to the light emitting surface, a distance between the semi-reflective transflective layer and the reflective layer is set so that light resonates in a light emission direction.

Furthermore, an organic electroluminescence element has been proposed in which a light emitting portion including a light emission layer and a wavelength conversion layer is disposed in a microcavity. An object is to absorb excitation light emitted by the light emission layer to narrow light emission wavelength distribution of long wavelength light emitted by the wavelength conversion layer, or to perform light distribution control for increasing forward radiation (see JP 2010-015785 A). The microcavity structure is provided with the semi-reflective transflective layer on the light emitting surface of the light emitting portion, and includes a reflective layer on the opposite surface to the light emitting surface, and an optical distance between both reflective surfaces is set to satisfy resonance conditions for both the excitation light and the long wavelength light.

### SUMMARY OF THE INVENTION

In an image display element for a glasses-like device, in order to achieve bright display, light emitted from pixels is preferably concentrated forward, and a configuration in which a light emitting portion is disposed in a microcavity is very attractive. However, when a microcavity structure is applied to a micro display element, the following problems exist.

In the micro display element, the pixels are made finer, and a pixel pitch in a plan view is a few micrometer (μm). In such fine pixels, a thickness of the light emitting portion (a length in a parallel direction with respect to a light emission direction) is approximately identical to a length in a horizontal direction (a length in a vertical direction with respect to the light emission direction). On the other hand, a reflective material needs to be disposed at an end portion in a horizontal direction of the light emitting portion to prevent light leakage (optical crosstalk) to adjacent pixels. Since the pixels are typically formed in a rectangular shape, confinement of light occurs in the horizontal direction. When the length in the horizontal direction of the light emitting portion satisfies the resonance condition, resonance in a vertical direction and resonance in the horizontal direction compete with each other, and a situation occurs in which sufficient light cannot be emitted in the vertical direction. Even when the length in the horizontal direction is designed not to satisfy the resonance condition, since variations occur in a process of determining a size of each pixel, pixels that also resonate in the horizontal direction are randomly generated at a constant rate. Since such a phenomenon increases variations in luminance among the pixels, a yield of micro display elements is reduced. Thus, the manufacturing cost is increased and commercialization becomes difficult.

An aspect of the present disclosure has been made in view of the problem described above, and an object of the present disclosure is to achieve an image display element that is made finer and has a microcavity structure capable of emitting light having narrow light emission wavelength distribution to be strongly distributed forward, the image display element reducing optical crosstalk, being improved in manufacturing yield, and supplied at a low price. To solve the above-described problem, an image display element according to an aspect of the present disclosure includes a plurality of pixels arranged in an array, each of the plurality of pixels including a micro light emitting element, and a driving circuit substrate including a driving circuit configured to supply a current to the micro light emitting element to cause the micro light emitting element to emit light, the micro light emitting element emits emission light in an opposite direction to the driving circuit substrate, the micro light emitting element includes a light emitting portion configured to generate the emission light, a reflection/transmission film provided on the light emitting portion at a part facing in a light emission direction, and a reflective surface provided on the light emitting portion at a part proximate to the driving circuit substrate, the reflection/transmission film and the reflective surface constitute a microcavity for the emission light, and a tilted reflective surface is provided on a side of the light emitting portion.

In addition, to solve the above-described problem, an image display element according to another aspect of the present disclosure includes a plurality of pixels arranged in an array, each of the plurality of pixels including a micro light emitting element, and a driving circuit substrate including a driving circuit configured to supply a current to the micro light emitting element to cause the micro light emitting element to emit light, the micro light emitting element emits emission light in an opposite direction to the driving circuit substrate, the micro light emitting element includes a light emitting portion configured to generate the emission light, a reflection/transmission film provided on the light emitting portion at a part facing in a light emission direction, and a reflective surface provided on the light emitting portion at a part proximate to the driving circuit substrate, the reflection/transmission film and the reflective surface constitute a microcavity for the emission light, and a concave-convex reflective surface is provided on a side of the light emitting portion.

According to an aspect of the present disclosure, the micro display element configured to prevent optical crosstalk between the micro light emitting elements adjacent to each other and to perform light distribution control so as to enhance forward radiation can be achieved at a low cost.

### BRIEF DESCRIPTION OF THE DRAWINGS

FIG. 1 is a cross-sectional schematic view of a pixel region of an image display element according to a first embodiment of the present disclosure.

FIG. 2 is a schematic plan view of the pixel region of the image display element according to the first embodiment of the present disclosure.

FIG. 3 is a cross-sectional schematic view of a pixel region of an image display element according to a second embodiment of the present disclosure.

FIG. 4 is a cross-sectional schematic view of a pixel region of an image display element according to a third embodiment of the present disclosure.

FIG. 5 is a cross-sectional schematic view of a pixel region of an image display element according to a fourth embodiment of the present disclosure.

FIG. 6 is a cross-sectional schematic view of a pixel region of an image display element according to a fifth embodiment of the present disclosure.

FIG. 7 is a cross-sectional schematic view of an image display element according to a sixth embodiment of the present disclosure.

FIG. 8 is a cross-sectional schematic view of a pixel region of an image display element according to a seventh embodiment of the present disclosure.

FIG. 9 is a cross-sectional schematic view of a pixel region of an image display element according to an eighth embodiment of the present disclosure.

FIG. 10 is a cross-sectional schematic view of an image display element according to a ninth embodiment of the present disclosure.

FIG. 11 is a cross-sectional schematic view of an image display element according to a tenth embodiment of the present disclosure.

FIG. 12 is a schematic plan view of a pixel region of the image display element according to the tenth embodiment of the present disclosure.

FIG. 13 is a cross-sectional schematic view of a pixel region of an image display element according to an eleventh embodiment of the present disclosure.

FIG. 14 is a cross-sectional schematic view of a pixel region of an image display element according to a twelfth embodiment of the present disclosure.

FIG. 15 is a cross-sectional schematic view of a pixel region of an image display element according to a thirteenth embodiment of the present disclosure.

FIG. 16 is a cross-sectional schematic view of a pixel region of an image display element according to a fourteenth embodiment of the present disclosure.

FIG. 17 is a schematic plan view of the pixel region of the image display element according to the fourteenth embodiment of the present disclosure.

### DETAILED DESCRIPTION OF THE INVENTION

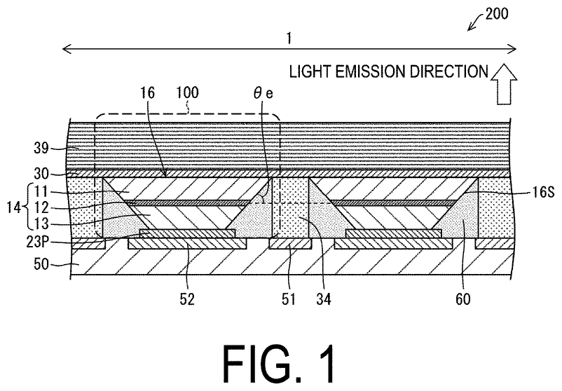

Hereinafter, embodiments of the present disclosure will be described with reference to FIG. 1 to FIG. 17, using an image display element including a plurality of micro light emitting elements as an example. Note that the image display element includes the plurality of micro light emitting elements and a driving circuit substrate 50, and the driving circuit substrate 50 supplies a current to the micro light emitting elements in a pixel region 1, and controls light emission. The micro light emitting elements are disposed in an array in the pixel region 1. The micro light emitting elements emit light in a direction opposite to the driving circuit substrate 50. The light emitted to the outside is referred to as emission light. Unless otherwise indicated, a surface from which the micro light emitting elements emit light into the air is referred to as a light emitting surface. Note that, in the description of the configuration of the image display element, unless otherwise indicated, the light emitting surface is referred to as an upper surface (first surface), a surface opposite to the light emitting surface is referred to as a lower surface (second surface), and side surfaces other than the upper surface and the lower surface are referred to as side surfaces. Similarly, the light emission direction is referred to as upward and the opposite direction is referred to as downward. A direction toward the air perpendicular to the light emitting surface is also referred to as forward.

An electrode proximate to the upper surface of the micro light emitting element is referred to as a first electrode, an electrode proximate to the lower surface is referred to as a second electrode, a conductive layer proximate to an upper surface of a compound semiconductor layer constituting the micro light emitting element is referred to as a first conductive layer, and a conductive layer proximate to a lower surface is referred to as a second conductive layer. When the compound semiconductor layer generates emission light in the micro light emitting element, the compound semiconductor layer serves as the light emitting portion. When the micro light emitting element includes an excitation light emitting element and a wavelength converter, excitation light emitted by the excitation light emitting element is absorbed by the wavelength converter to be converted to light (long wavelength light) having a wavelength longer than that of the excitation light, and the converted light is emitted to the outside. Thus, the long wavelength light serves as emission light, and the wavelength converter serves as the light emitting portion. The excitation light emitting element and the wavelength converter are layered in order on the driving circuit substrate 50.

In the driving circuit substrate 50, a micro light emitting element driving circuit configured to control a current to be supplied to each of the micro light emitting elements is disposed in the pixel region 1. A row selection circuit configured to select each row of the micro light emitting elements disposed in a two-dimensional matrix, a column signal output circuit configured to output a light emission signal to each column, an image processing circuit configured to calculate a light emission signal based on an input signal, an input/output circuit, and the like are disposed at the outside of the pixel region 1. Although the above configuration is commonly used, the circuit arrangement on the driving circuit substrate 50 is not limited thereto. An N-drive electrode 51 (first drive electrode) and a P-drive electrode 52 (second drive electrode) that are connected to the micro light emitting element are disposed on a surface at a bonding surface part of the driving circuit substrate 50. The driving circuit substrate 50 is typically a silicon substrate (semiconductor substrate) formed with an LSI, or a glass substrate formed with a TFT, and can be manufactured by known techniques, and thus, its function and configuration will not be described in detail.

Note that in the figures, the micro light emitting element is depicted in a shape close to a square, but the shape of the micro light emitting element is not particularly limited thereto. The micro light emitting element may have a variety of planar shapes, such as a rectangle, a polygon, a circle, or an oval, and the largest length is assumed to be equal to or shorter than 5 μm. The image display element is assumed to have at least three thousands micro light emitting elements integrated in the pixel region 1.

### First Embodiment

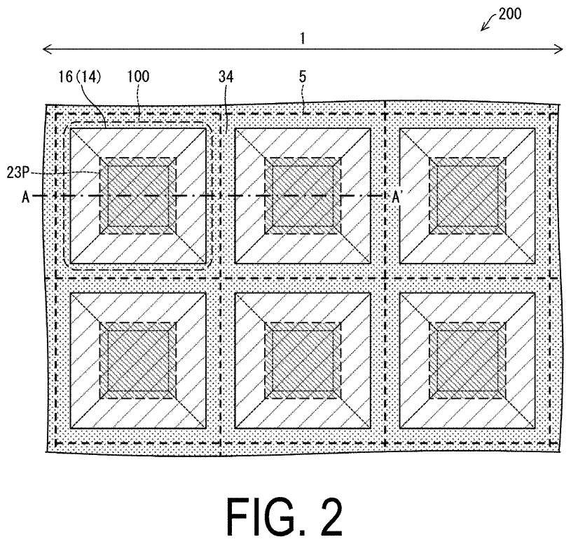

Configuration of Image Display Element 200 FIG. 1 is a cross-sectional schematic view of the pixel region 1 of the image display element 200 according to a first embodiment of the present disclosure. FIG. 2 is a schematic plan view of the pixel region 1 of the image display element 200 according to the first embodiment of the present disclosure. As illustrated in FIG. 2, an upper surface of the image display element 200 is provided with the pixel region 1 in which a plurality of pixels 5 are disposed in an array. In the present embodiment, the image display element 200 is a monochrome display element, and each of the pixels 5 includes one monochrome micro light emitting element 100. In this configuration, an upper surface of the micro light emitting element 100 is a light emitting surface.

The micro light emitting element 100 includes a main body 16 formed of a compound semiconductor layer 14, a P electrode 23P (second electrode), and an N electrode 30 (first electrode). The compound semiconductor layer 14 includes a light emission layer 12 configured to emit emission light, an N-side layer 11 (first conductive layer) configured to inject electrons into the light emission layer 12, and a P-side layer 13 (second conductive layer) configured to inject positive holes into the light emission layer 12. In this configuration, the light emitting portion of the micro light emitting element 100 is the main body 16, and light generated in the light emission layer 12 is emitted to the outside. The compound semiconductor layer 14 is a nitride semiconductor (AlInGaN-based) in a case of a micro light emitting element configured to emit light in a wavelength band from ultraviolet light to red, and is an AlInGaP-based semiconductor in a case of emitting light in a wavelength band from yellow-green to red, for example. In a wavelength band from red to infrared light, the compound semiconductor layer 14 is an AlGaAs-based semiconductor layer, or a GaAs-based semiconductor layer.

In the following, as for the compound semiconductor layer 14 constituting the main body 16 of the micro light emitting element 100, only a configuration in which the N-side layer 11 is disposed to face in the light emission direction will be described, but a configuration in which the P-side layer 13 is disposed to face in the light emission direction is also applicable. Although each of the N-side layer 11, the light emission layer 12, and the P-side layer 13 is typically not a single layer and is optimized to include a plurality of layers, this is not directly related to the configuration according to the present disclosure, and thus, the detailed structures of the respective layers will not be described. Typically, although the light emission layer is sandwiched between the N-type layer and the P-type layer, the N-type layer and the P-type layer may include a non-doped layer or a layer with a dopant having opposite electrical conductivity in some cases, and thus, will be denoted below as an N-side layer and a P-side layer, respectively.

FIG. 1 illustrates a cross-sectional view taken along an A-A′ line in FIG. 2. As illustrated in FIG. 1, the P electrode 23P of the micro light emitting element 100 is formed on the second surface, and is connected to the corresponding P-drive electrode 52 on the driving circuit substrate 50. The N electrode 30 is disposed proximate to the light emitting surface of the main body 16, and is connected to the N-drive electrode 51 on the driving circuit substrate 50 via a first partition 34 having electrical conductivity. A current supplied from the P-drive electrode 52 to the micro light emitting element 100 flows from the P electrode 23P to the P-side layer 13 to be injected into the light emission layer 12. The current flows from the N-side layer 11 through the N electrode 30 to the N-drive electrode 51. In this way, according to the amount of the current supplied from the driving circuit substrate 50, the micro light emitting element 100 emits light at a predetermined intensity. Note that the connection of the N electrode 30 and the N-drive electrode 51 may be performed in the pixel region 1 as illustrated in FIG. 1, or may be performed in a connection region disposed outside the pixel region 1. As illustrated in FIG. 1, the N electrode 30 may be continuous across the plurality of micro light emitting elements 100, or may be divided for each of the pixels 5.

The micro light emitting elements 100 are individually divided, and the side surface of each micro light emitting element 100 is covered by a protection portion 60 having an electrically insulating property. The heights of the upper surfaces of the main body 16, the protection portion 60, and the first partition 34 are preferably substantially equal to one another. This can facilitate the formation of the N electrode 30 and the reflection/transmission film 39. Side surfaces 16S of the main body 16 are tilted in a range from 30 degrees to 80 degrees (θe) with respect to the surface of the driving circuit substrate 50. The side surfaces of the main body 16 may have different tilt angles θe, but the tilt angles θe of all the side surfaces are preferably in a range from 30 degrees to 80 degrees. Additionally, in FIG. 1, the side surfaces 16S are uniformly tilted from the P electrode 23P to the N electrode 30, but only a portion including the light emission layer 12 may be tilted, and the other portion may be made vertical, or the tilt angle may be closer to 90 degrees. That is, the upper portion and the lower portion of the main body 16 may have the side surfaces that are substantially vertical, and the central portion may be tilted in the range from 30 degrees to 80 degrees. In this case, at least a half region of the side surface 16S is preferably tilted. In addition, when the tilts are not uniform because of the manufacturing method, an average tilt angle of the tilted portions is preferably within the range described above.

The P electrode 23P is a reflective surface disposed proximate to the second surface, and contains a metal material having high reflectivity such as silver, aluminum or the like. The reflective surface is at least in contact with a surface of the P-side layer 13 proximate to the second surface, and preferably covers the second surface of the micro light emitting element 100 as wide as possible. This is because the light leakage toward the driving circuit substrate 50 is reduced and the light emission efficiency is improved. Note that in this configuration, the reflective surface disposed proximate to the second surface is formed of metal in order to be used as both the reflective surface and the P electrode, but the P electrode 23P may be formed of a transparent conductive film, and a dielectric multilayer film may be disposed below the transparent conductive film. In such a case, the reflective surface is formed of the dielectric multilayer film.

The N electrode 30 may be a transparent conductive film, for example, may be an oxide semiconductor such as Indium-Tin-Oxide (ITO), Indium-Zinc-Oxide (IZO) or the like, or may be a silver nanofiber film or the like. To reduce absorption of light, the N electrode 30 is preferably as thin as possible.

The reflection/transmission film 39 is a dielectric multilayer film, and exhibits high transmittance for vertical incident light at the wavelength of emission light, but reflects light having a large incident angle. The reflection/transmission film 39 has a structure in which a film having a large refractive index at the wavelength of emission light (for example, a titanium oxide film, a silicon nitride film, a niobium oxide film, or the like), and a film having a small refractive index (such as a silicon oxide film) are alternately layered.

To prevent light leakage into the adjacent pixels, the first partition 34 that does not transmit light therethrough preferably surrounds the periphery of the pixel 5. In a case where the first partition 34 does not transmit light therethrough, the protection portion 60 may be transparent. Otherwise, the protection portion 60 preferably has a light blocking function due to reflection or absorption. By preventing light leakage into the adjacent pixels, contrast and color purity can be increased.

A distance between the reflective surface (second electrode in this embodiment) and the light emission layer 12, that is, a thickness of the P-side layer 13 (second conductive layer), is preferably set so that when light emitted from the light emission layer 12 toward the second electrode is reflected at the reflective surface, and is directed toward the first electrode, the light interferes with light directly directed from the light emission layer 12 toward the first electrode so as to intensify each other. In a case where its phase does not change when the light is reflected at the reflective surface, the thickness of the P-side layer (second conductive layer) is preferably an integer multiple of a half wavelength of light in an interior of the compound semiconductor layer 14. When the compound semiconductor layer 14 is made of gallium nitride, the thickness is substantially an integer multiple of 90 nm, such as 90 nm, 180 nm, 270 nm, and 360 nm. Note that these values are not exact. This is because, according to the layer configuration in the interior of the compound semiconductor layer 14, the refractive index slightly changes, and a position in the light emission layer 12, where light is generated most strongly, is altered.

A distance between the reflective surface and the reflection/transmission film 39 is preferably set so that the microcavity is configured with respect to emission light traveling in an emission direction. The distance is set so that emission light traveling in the emission direction resonates between the reflective surface and the reflection/transmission film 39. That is, on this condition, when emission light reflected at the reflection/transmission film 39 is reflected by the second electrode, and then, is incident on the reflection/transmission film 39 again, the emission light interferes with emission light that is transmitted through the reflection/transmission film 39 without being reflected at the reflection/transmission film 39 so as to intensify each other. When there is no phase change at the time of reflection at the reflective surface and the reflection/transmission film 39, an optical distance between the reflective surface and the reflection/transmission film 39 is set to an integer multiple of a half wavelength of the emission light.

In this configuration, the side surfaces 16S of the main body 16 are tilted reflective surfaces, and are tilted in an opened manner toward the light emission direction. Thus, the emission light horizontally traveling in the main body 16 does not resonate. In a case where the side surface 16S is a vertical surface, dimensional variations of the main body 16 in a horizontal direction may result in a resonant state between the side surfaces 16S facing each other. In such a pixel, the amount of emission light emitted in the light emission direction decreases, so that luminance variations between the pixels increase, and the image display element 200 may become a defective product in some cases. For example, when a length of one side of the main body 16 in the horizontal direction is 2 μm and the dimension varies ±10%, the dimension varies γ200 nm. As described above, when a resonance condition occurs at an interval of 90 nm, pixels in a resonant state and pixels in a non-resonant state are frequently generated due to the dimensional variations. Moreover, of two sets of the sides facing each other, there are a case where only one set is in the resonant state and a case where both of two sets are in the resonant state. As the resonant state increases in the horizontal plane, the light output forward is decreased because the microcavity effect in the light emission direction is weakened. Thus, the luminance variations are increased. Therefore the tilted side surfaces is vital to achieve good luminance uniformity between the pixels and the luminace variation can be suppressed to be less than 15%.

In this configuration, light emitted in the horizontal direction from the light emission layer 12 is reflected upward at the side surface 16S, and thus, a part of the light is transmitted through the reflection/transmission film 39 to be emitted to the outside. Thus, light extraction efficiency can be increased by tilting the side surfaces 16S in an opened manner toward the light emission direction. In addition, the light emitted to the outside by being reflected at the side surface 16S is transmitted through the reflection/transmission film 39, and thus, is not so different from the light emitted to the outside without being reflected at the side surface 16S in terms of wavelength distribution or emission angle distribution. Thus, the amount of light can be increased without changing the quality of the emission light.

The tilted side surface 16S has another advantage. When light is directly incident on the reflection/transmission film 39 from the light emission layer 12 at a large incident angle, the light is reflected at the reflection/transmission film 39. In a case where the side surface 16S is vertical, such light is not emitted to the outside because the angle at which the light is incident on the reflection/transmission film 39 does not change even when reflection is repeated over and over. However, in a case where the side surface 16S is tilted, the incident angle on the reflection/transmission film 39 changes due to reflection at the side surface 16S, and thus, a case may occur in which the light is emitted to the outside. In this way, the light emission efficiency can be increased.

As described above, by tilting the side surface 16S of the main body 16 serving as the light emitting portion, the emission light is prevented from resonating in the horizontal direction in the light emitting portion. As a result, even when the light emitting portions have dimensional variations in the horizontal direction, luminance variations among the micro light emitting elements 100 are prevented, and a manufacturing yield of the image display elements 200 can be increased. That is, image display elements having high contrast, high color purity, and low power consumption can be achieved at low cost.

### Second Embodiment

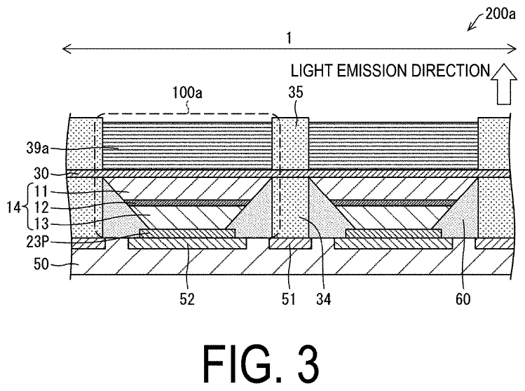

Another embodiment of the present disclosure will be described below with reference to FIG. 3. Note that, for convenience of explanation, components having the identical function to those described in the above-described embodiment will be denoted by the identical reference signs, and descriptions of those components will be omitted.

In the first embodiment described above, to suppress optical crosstalk, the main body 16 is divided for each micro light emitting element 100, and the first partition 34 is provided between the pixels, but the reflection/transmission film 39 is formed continuously across a plurality of pixels. This is because light guided in the reflection/transmission film 39 is hardly emitted to the outside and is very less likely to generate optical crosstalk. On the other hand, in an image display element 200a according to a second embodiment illustrated in a cross-sectional schematic view of FIG. 3, a reflection/transmission film 39a is also divided for each pixel by a third partition 35. In other respects, there is no difference from the first embodiment.

When the pixels become smaller, the amount of light entering from the adjacent pixels through the reflection/transmission films 39 may not be negligible. In particular, when the side surface 16S is tilted, such light from neighbor pixels is likely to be reflected in the main body 16 to be emitted to the outside. To prevent such optical crosstalk generated through the reflection/transmission film 39, it is preferable to divide the reflection/transmission film 39 for each pixel, like the reflection/transmission film 39a.

The structure illustrated in FIG. 3 can be manufactured by forming grooves that divide the reflection/transmission film 39 after the structure illustrated in FIG. 1 is made, and embedding metal films or the like that serve as the third partitions 35 in the grooves.

According to the present embodiment, similar effects to those of the first embodiment can be also achieved.

### Third Embodiment

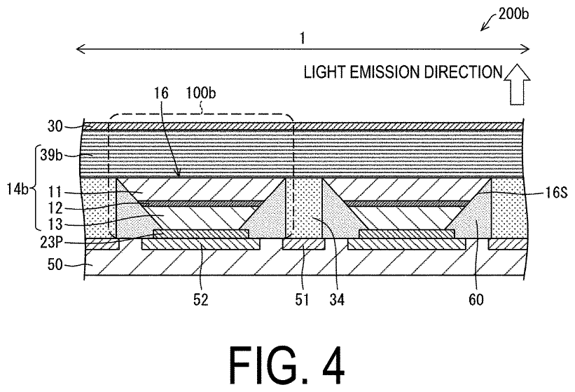

Another embodiment of the present disclosure will be described below with reference to FIG. 4. Note that, for convenience of explanation, components having the identical function to those described in the above-described embodiment will be denoted by the identical reference signs, and descriptions of those components will be omitted.

In the first and second embodiments described above, a dielectric multilayer film is used as the reflection/transmission film 39 (39a), but this configuration is obtained by using a compound semiconductor. Thus, in FIG. 4, a compound semiconductor layer 14b can be obtained by combining the main body 16 including the N-side layer 11, the light emission layer 12, and the P-side layer 13, and a reflection/transmission film 39b.

The first partition 34 is electrically connected to the reflection/transmission film 39b. The reflection/transmission film 39b has N-type electrical conductivity and electrically connects the N electrode 30 provided on the upper surface of the reflection/transmission film 39b and the N-side layer 11. The reflection/transmission film 39b is continuous across pixels in a similar manner to that in the first embodiment, but may be divided for each pixel in a similar manner to that in the second embodiment. When the electrical conductivity of the reflection/transmission film 39b is sufficiently high, the transparent conductive film that is the N electrode 30 may be omitted, and the reflection/transmission film 39b can also serve as the N electrode 30.

In the structure illustrated in FIG. 4, the reflection/transmission film 39b can be fabricated when the compound semiconductor layer is grown, and thus, unlike the structure illustrated in FIG. 1, there is an advantage that the reflection/transmission film 39 need not be formed separately from the compound semiconductor layer 14, which makes the manufacturing process simple and convenient.

According to the present embodiment, similar effects to those of the first embodiment can be also achieved.

### Fourth Embodiment

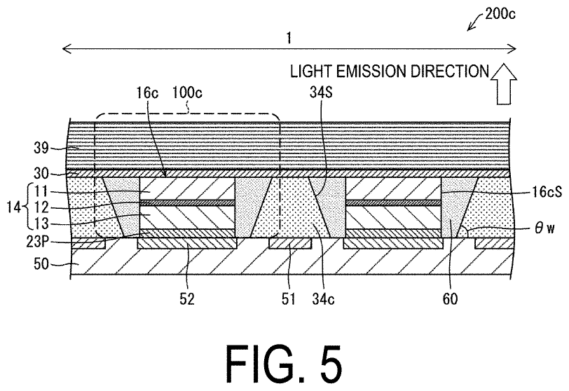

Another embodiment of the present disclosure will be described below with reference to FIG. 5. Note that, for convenience of explanation, components having the identical function to those described in the above-described embodiment will be denoted by the identical reference signs, and descriptions of those components will be omitted.

In the first to third embodiments described above, the side surfaces 16S of the main body 16 are tilted, but in this configuration, the side surfaces 16S are not tilted, and side surfaces (first partition side surfaces 34S) of a first partition 34c are tilted. The other points are similar to those in the first embodiment.

In this configuration, side surfaces 16cS of a main body 16c formed of the compound semiconductor layer 14 need not be tilted. A thickness of the main body 16c and a distance between the light emission layer 12 and the second electrode need to satisfy a similar relationship to that in the first embodiment. The first partition side surface 34S of the first partition 34c is tilted in a range from 30 degrees to 80 degrees (θ_{w}) with respect to the surface of the driving circuit substrate 50. The tilt angle θw is preferably in a range from 30 degrees to 60 degrees. The first partition side surface 34S is a tilted reflective surface, and preferably has high reflectivity with respect to a wavelength of emission light. Thus, in a case where the emission light is visible light, the first partition 34c may be formed of metal having high reflectivity such as silver or aluminum. The first partition 34c may be formed by performing vapor deposition of these types of metal by using a lift-off method, or may be deposited as a thin film by using a vapor deposition method or a sputtering method to be processed by using a lithography technique and a dry etching technique. During processing, the first partition side surface 34S needs to be controlled to be tilted. When the emission light is infrared light, gold can be used as a material of the first partition 34c. Only a surface layer of the first partition 34c may be formed of metal having high reflectivity. For example, a metal film having high reflectivity may be deposited after a pattern is formed by using a resist. In other words, a configuration may be applicable in which an interior of the first partition 34c is formed of a resin material, and the surface of the first partition side surface 34S is formed of a metal film having high reflectivity.

Since at least the surface of the first partition 34c is made of metal having high reflectivity, light is not transmitted through the surface. Thus, leakage of light into adjacent pixels can be prevented and optical crosstalk can be reduced.

The protection portion 60 is a transparent insulating film. The protection portion 60 may be an inorganic film formed of silicon dioxide (SiO₂), silicon nitride (SiN), titanium dioxide (TiO₂) or the like, may be a resin film such as acrylic resin, or may be made of silicone resin.

In this configuration, since most of light emitted in a horizontal direction from the light emission layer 12 is transmitted through the side surface 16cS, and then, is reflected by the first partition side surface 34S, occurrence of a resonant state in the horizontal direction can be reduced in a similar manner to those in the other embodiments.

In this configuration, the light emitted in the horizontal direction from the light emission layer 12 is emitted into the protection portion 60, and then, is reflected upward by the first partition side surface 34S to be incident on the reflection/transmission film 39. The light satisfying the transmission conditions of the reflection/transmission film 39 is emitted to the outside, and thus, is not so different from the light directly emitted from the interior of the main body 16c in terms of wavelength distribution and radiation angle distribution. As a result, similar effects to those of the first embodiment can be achieved.

### Fifth Embodiment

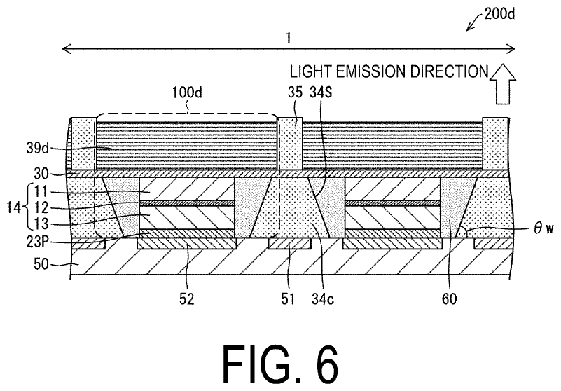

Another embodiment of the present disclosure will be described below with reference to FIG. 6. Note that, for convenience of explanation, components having the identical function to those described in the above-described embodiment will be denoted by the identical reference signs, and descriptions of those components will be omitted.

In the fourth embodiment described above, to suppress optical crosstalk, the main body 16c is divided for each of the micro light emitting elements 100, and the first partition 34c is provided between the pixels, but the reflection/transmission film 39 is formed continuously across a plurality of pixels. This is because light guided in the reflection/transmission film 39 is hardly emitted to the outside and is very less likely to generate optical crosstalk. On the other hand, in an image display element 200d illustrated in the cross-sectional schematic view of FIG. 6, a reflection/transmission film 39d is also divided for each pixel by the third partition 35. In other respects, there is no difference from the fourth embodiment.

When the pixels become smaller, the amount of light entering from the adjacent pixels through the reflection/transmission films 39 may not be negligible. In particular, in a case where the first partition side surface 34S is tilted, such light is highly likely to be reflected by the first partition side surface 34S to be emitted to the outside. In this way, to prevent optical crosstalk generated through the reflection/transmission film 39, it is preferable to divide the reflection/transmission film 39 for each pixel, similar to the reflection/transmission film 39d.

The structure illustrated in FIG. 6 can be formed by forming grooves that divide the reflection/transmission film 39 after forming the structure illustrated in FIG. 5, and embedding metal films or the like serving as the third partitions 35 in the grooves.

According to the present embodiment, similar effects to those of the first embodiment can be also achieved.

### Sixth Embodiment

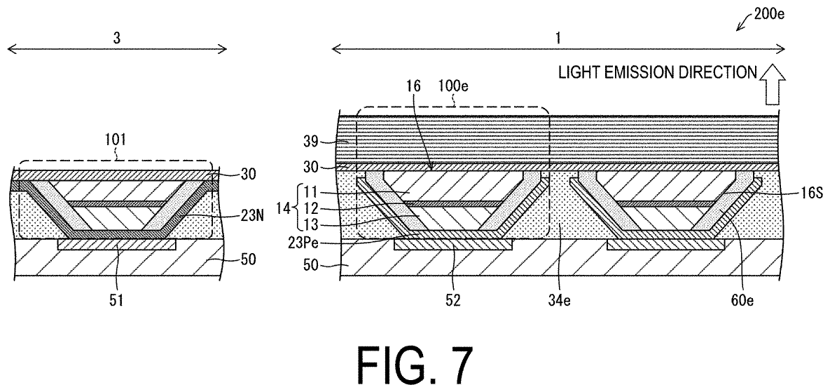

Another embodiment of the present disclosure will be described below with reference to FIG. 7. Note that, for convenience of explanation, components having the identical function to those described in the above-described embodiment will be denoted by the identical reference signs, and descriptions of those components will be omitted.

In an image display element 200e illustrated in FIG. 7, the main body 16 of a micro light emitting element 100e has tilted side surface 16S in a similar manner to that in the first embodiment, but the image display element 200e differs from the image display element 200 according to the first embodiment in that a protection portion 60e is disposed at the outer side of the tilted side surface 16S (tilted reflective surface), and a P electrode 23Pe covers the outer side of the protection portion 60e. The N electrode 30 and the reflection/transmission film 39 are similar to those in the first embodiment. The N electrode 30 is connected to the N-drive electrode 51 via a connection element 101 in a connection region 3 provided outside the pixel region 1.

Since the leakage of light from the main body 16 to the adjacent pixels is prevented by the P electrode 23Pe, the first partition 34e can be formed of transparent resin. Thus, in the manufacturing process, it is only required that a gap is filled with transparent resin or the like after a structure including the main body 16, the protection portion 60e, and the P electrode 23Pe is disposed on the driving circuit substrate 50, and thus there is an advantage that the manufacturing process can be simplified. After the first partition 34e is formed, the surface of the main body 16 at the light emission part is exposed, the N electrode 30 is formed, and the reflection/transmission film 39 is formed.

The connection element 101 has a similar structure to that of the micro light emitting element 100e. A connecting electrode 23N connects the N-drive electrode 51 and the N electrode 30. The connecting electrode 23N may be formed simultaneously with the P electrode 23Pe of the micro light emitting element 100e. In this case, the connecting electrode 23N and the P electrode 23Pe are formed of an identical material.

According to this configuration, similar effects to those of the first embodiment can be achieved.

### Seventh Embodiment

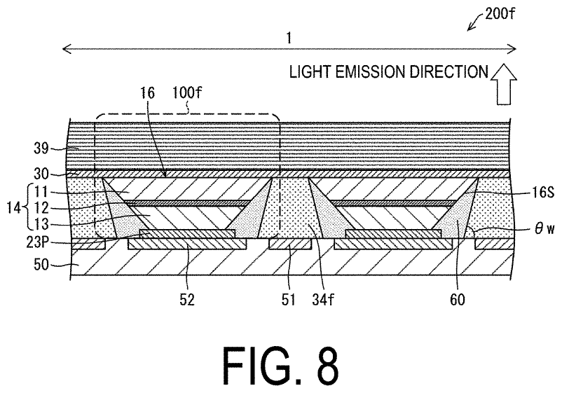

Another embodiment of the present disclosure will be described below with reference to FIG. 8. Note that, for convenience of explanation, components having the identical function to those described in the above-described embodiment will be denoted by the identical reference signs, and descriptions of those components will be omitted.

An image display element 200f illustrated in FIG. 8 differs from the image display element 200 according to the first embodiment in that side surfaces of first partitions 34f of a micro light emitting element 100f are slightly tilted in an opened manner with respect to a light emission direction.

Light emitted in a horizontal direction from the light emission layer 12 is reflected by the side surface 16S (tilted reflective surface) to be incident on the reflection/transmission film 39, but light emitted orthogonal to the side surface 16S from the light emission layer 12 is transmitted through the side surface 16S to the protection portion 60. Such light is not likely to be emitted to the outside as it is. However, when the side surface of the first partition 34f is tilted in a range approximately from 60 degrees to 80 degrees (θw) with respect to the surface of the driving circuit substrate 50, an incident angle at which the light is incident on the reflection/transmission film 39 changes each time the light is reflected at the side surface of the first partition 34f. As a result, the light transmits through the reflection/transmission film 39 after a plurality of reflections. In this way, the amount of the light emitted to the outside from the reflection/transmission film 39 can be increased.

According to this configuration, similar effects to those of the first embodiment can be achieved.

### Eighth Embodiment

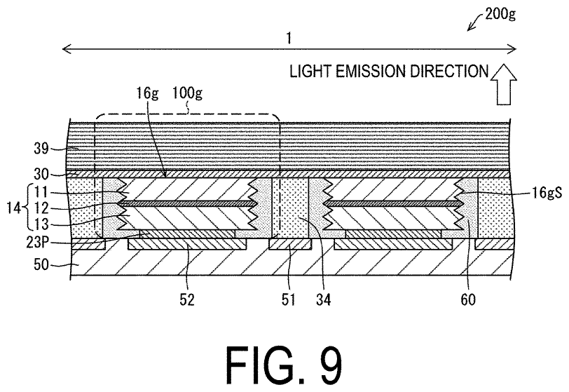

Another embodiment of the present disclosure will be described below with reference to FIG. 9. Note that, for convenience of explanation, components having the identical function to those described in the above-described embodiment will be denoted by the identical reference signs, and descriptions of those components will be omitted.

An image display element 200g illustrated in FIG. 9 differs from the image display element 200 according to the first embodiment in that concaves and convexes are provided at side surfaces 16gS of a main body 16g of a micro light emitting element 100g.

In the first embodiment described above, to prevent occurrence of a resonant state in a horizontal direction, light propagating direction is changed by reflecting at the tilted side surface 16S (tilted reflective surface), but when the concaves and convexes are provided on the side surfaces 16gS as in the present embodiment, a travel direction of light can be changed by an effect of reflection, scattering, diffraction, or the like. In other words, in the present embodiment, the occurrence of the resonant state is prevented by the side surfaces 16gS serving as the concave-convex reflective surfaces. That is, since the side surfaces 16gS are uneven, the resonant state is prevented to appear. As a result, similar effects to those of the first embodiment can be achieved. Whether the effects of reflection, scattering, diffraction, and the like are strong or weak change according to the scale of size and regularity of the concaves and the convexes. When the scale of the size of the concaves and the convexes is larger than the wavelength of light in the main body 16g, reflection is effective. When the scale is approximately equal to the wavelength of light, scattering is effective. When the concaves and the convexes are arranged in a regular manner and intervals are within a range from approximately the wavelength of light in the main body 16g to three times the wavelength, diffraction is effective.

Light incident orthogonally to the side surface 16gS changes its travel direction so as to travel upward and downward by reflection, scattering, diffraction, or the like at the side surface 16gS. A part of the light can increase the amount of light emitted to the outside from the reflection/transmission film 39. Although light incident on the side surface 16gS once is not emitted to the outside, repeated incidence of the light on the side surface 16gS increases opportunities for emission from the reflection/transmission film 39 to the outside. In this way, the occurrence of the resonant state can be prevented, and light extraction efficiency can be greatly increased. Furthermore, light transmitted through the side surface 16gS to the protection portion 60 is prevented from leaking out to the adjacent pixels by the first partition 34.

According to this configuration, similar effects to those of the first embodiment can be achieved.

Note that, instead of using the side surfaces 16gS as the concave-convex reflective surfaces as in this configuration, the main body side walls may be made vertical as in the fourth embodiment and the side walls of the first partition may be provided with concaves and convexes or uneven. In this case, the side wall of the first partition serves as the concave-convex reflective surface. Such a configuration can also achieve similar effects to those of this configuration.

### Ninth Embodiment

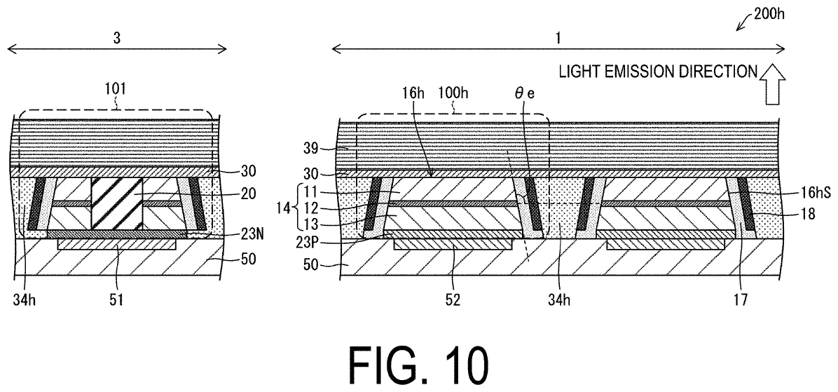

Another embodiment of the present disclosure will be described below with reference to FIG. 10. Note that, for convenience of explanation, components having the identical function to those described in the above-described embodiment will be denoted by the identical reference signs, and descriptions of those components will be omitted.

FIG. 10 is a cross-sectional schematic view of an image display element 200h according to a ninth embodiment of the present disclosure. As illustrated in FIG. 10, the image display element 200h includes the pixel region 1 in which a plurality of micro light emitting elements 100h are arranged in an array, and the connection region 3 connecting first electrodes of the micro light emitting elements 100h. This point is identical to that of FIG. 7 in the sixth embodiment. The present embodiment differs from the first embodiment in that side surfaces 16hS (tilted reflective surfaces) of a main body 16h are tilted in a closed manner with respect to a light emission direction.

In a case where the side walls are tilted to prevent occurrence of a resonant state of light in a horizontal direction, the side walls may be tilted in an opened manner or a closed manner with respect to the light emission direction. In other words, a tilt angle θe may be larger than 90 degrees or smaller than 90 degrees with respect to the surface of the driving circuit substrate 50. As in the sixth embodiment, when θe<90 degrees is satisfied, an effect of increasing light emission efficiency is exerted by reflecting the light emitted in the horizontal direction toward the light emission direction. On the other hand, when θe>90 degrees is satisfied, as in the present embodiment, the light emitted in the horizontal direction is confined in the interior of the main body 16h. Thus, the forward radiation can be enhanced due to inductive radiation after reabsorption in the light emission layer 12.

The N electrode 30 is connected to the N-drive electrode 51 on the driving circuit substrate 50 by the connection element 101. The connection element 101 includes the compound semiconductor layer 14, a through hole electrode 20 that penetrates the compound semiconductor layer 14, a connecting electrode 23N provided proximate to the lower surface of the compound semiconductor layer 14, and the N electrode 30. The connecting electrode 23N connected to the N-drive electrode 51 and the N electrode 30 are electrically connected by using the through hole electrode 20.

The main bodies 16h of the micro light emitting elements 100h are individually divided. A protection film 17, which is a transparent insulating film, and a reflective film 18 are disposed on the main body side surface 16hS of the micro light emitting element 100h. A first partition 34h is disposed between the main bodies 16h. Heights of the upper surfaces of the main body 16h and the first partition 34h are preferably substantially equal. As a result, formation of the N electrode 30 and the reflection/transmission film 39 can be facilitated. In the interior of the main body 16h, the protection film 17 and the reflective film 18 are disposed so that the reflectivity becomes high, when the emission light is reflected at the side surface 16hS. This is because loss of the emission light is to be reduced. The protection film 17 is, for example, an insulating film, such as a SiO₂ film, having a smaller refractive index than that of the compound semiconductor layer 14 and not absorbing emission light. The reflective film 18 may be a highly reflective metal film containing silver or aluminum, or a dielectric multilayer film. The first partition 34h has insulating properties. Furthermore, the first partition 34h may have light-blocking properties or light-transmitting properties. Optical crosstalk can be suppressed because the reflective film 18 covers the periphery of the light emitting portion.

According to this configuration, similar effects to those of the first embodiment can be achieved.

### Tenth Embodiment

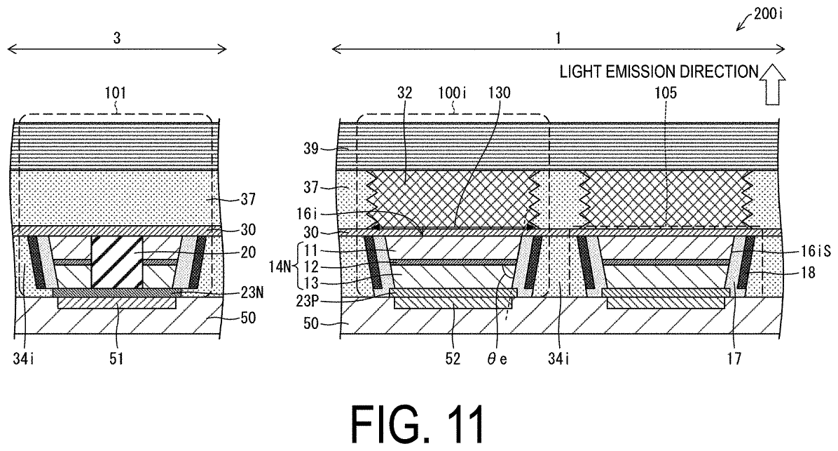

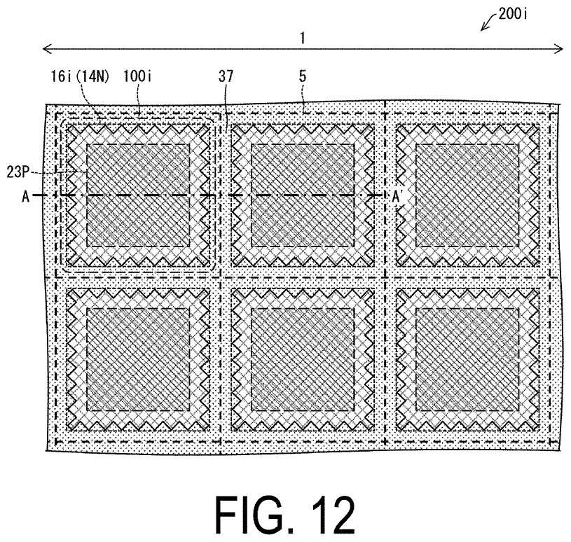

Another embodiment of the present disclosure will be described below with reference to FIG. 11 and FIG. 12. Note that, for convenience of explanation, components having the identical function to those described in the above-described embodiment will be denoted by the identical reference signs, and descriptions of those components will be omitted.

### Configuration of Image Display Element 200i

FIG. 11 is a cross-sectional schematic view of an image display element 200i according to a tenth embodiment of the present disclosure. A micro light emitting element 100i constituting the image display element 200i includes the excitation light emitting element 105 and the wavelength converter 32. As illustrated in FIG. 11, the image display element 200i includes the pixel region 1 in which a plurality of pixels 5 are arranged in an array, and the connection region 3 connecting the first electrodes of the excitation light emitting elements 105. FIG. 12 is a schematic plan view of the pixel region 1 of the image display element 200i according to the tenth embodiment of the present disclosure. In the present embodiment, the image display element 200i is a monochrome display element, and each of the pixels 5 includes one monochrome micro light emitting element 100i. In this configuration, an upper surface of the micro light emitting element 100i is a light emitting surface.

The excitation light emitting element 105 emits blue light, near-ultraviolet light, or ultraviolet light as excitation light. The excitation light emitting element 105 includes a main body 16i formed of a nitride semiconductor layer 14N, the P electrode 23P (second electrode), and the N electrode 30 (first electrode). The nitride semiconductor layer 14N (AlInGaN-based) includes the light emission layer 12 configured to emit light, the N-side layer 11 (first conductive layer) configured to inject electrons into the light emission layer 12, and the P-side layer 13 (second conductive layer) configured to inject holes into the light emission layer 12. Note that in FIG. 11, a configuration is illustrated in which the nitride semiconductor layer 14N constituting the excitation light emitting element 105 is individually divided for each pixel 5, but a part or all of the nitride semiconductor layer 14N may be continuous across the adjacent pixels 5.

In the following, as for the nitride semiconductor layer 14N constituting the main body 16i of the excitation light emitting element 105, only a configuration in which the N-side layer 11 is disposed to face in the light emission direction will be described, but a configuration in which the P-side layer 13 is disposed to face in the light emission direction is also applicable. Although each of the N-side layer 11, the light emission layer 12, and the P-side layer 13 is typically not a single layer and is optimized to include a plurality of layers, this is not directly related to the configuration according to the present disclosure, and thus, the detailed structures of the respective layers will not be described. Typically, although the light emission layer is sandwiched between the N-type layer and the P-type layer, the N-type layer and the P-type layer may include a non-doped layer or a layer with a dopant having opposite electrical conductivity in some cases, and thus, will be denoted below as an N-side layer and a P-side layer, respectively.

FIG. 11 illustrating the pixel region 1 is a cross-sectional view taken along an A-A′ line in FIG. 12. As illustrated in FIG. 11, the P electrode 23P of the excitation light emitting element 105 is formed on the second surface, and is connected to the corresponding P-drive electrode 52 on the driving circuit substrate 50. The N electrode 30 is disposed proximate to the light emitting surface of the main body 16i, and is connected to the N-drive electrode 51 on the driving circuit substrate 50 by using the connection element 101 in the connection region 3. The connection element 101 includes the nitride semiconductor layer 14N, the through hole electrode 20 that penetrates the nitride semiconductor layer 14N, the connecting electrode 23N provided proximate to the lower surface of the nitride semiconductor layer 14N, and the N electrode 30. The connecting electrode 23N connected to the N-drive electrode 51 and the N electrode 30 are electrically connected by using the through hole electrode 20. A current supplied from the P-drive electrode 52 to the excitation light emitting element 105 flows from the P electrode 23P to the P-side layer 13 to be injected into the light emission layer 12. The current flows from the N-side layer 11 to the N-drive electrode 51 through the N electrode 30, the through hole electrode 20, and the connecting electrode 23N. In this way, according to the amount of the current supplied by the driving circuit substrate 50, the excitation light emitting element 105 emits light at a predetermined intensity.

The excitation light emitting elements 105 are preferably individually divided. The protection film 17, which is a transparent insulating film, and the reflective film 18 are disposed on a side surface 16iS of the excitation light emitting element 105. As a result, leakage of excitation light from the excitation light emitting element 105 to adjacent pixels can be reduced, and contrast and color purity can be increased. The first partition 34i is disposed between the excitation light emitting elements 105. The heights of the upper surfaces of the excitation light emitting element 105 and the first partition 34i are preferably substantially equal. As a result, formation of the N electrode 30, the wavelength converter 32, and the reflection/transmission film 39 can be facilitated. In the interior of the main body 16i, the protection film 17 and the reflective film 18 are disposed so that the reflectivity when light is reflected at the side surface 16iS becomes high. This is because loss of the excitation light is to be reduced. The protection film 17 is, for example, an insulating film, such as a SiO₂ film, having a smaller refractive index than that of the nitride semiconductor layer 14N and not absorbing excitation light or long wavelength light. The reflective film 18 may be a highly reflective metal film containing silver or aluminum, or a dielectric multilayer film.

A thickness of the P-side layer 13 (second conductive layer), of the nitride semiconductor layer 14N constituting the main body 16i, is preferably set to an integer multiple of a half wavelength of excitation light in the nitride semiconductor layer 14N. On this condition, excitation light E1 that travels upward from the light emission layer 12, and excitation light E2 that travels downward and then is reflected upward by the P electrode 23P interferes with each other so as to intensify each other. By satisfying this condition, excitation light can be efficiently emitted upward, that is, toward the wavelength converter 32.

The side surface 16iS is preferably slightly tilted as illustrated in FIG. 11. When the side surface 16iS is a vertical surface, the excitation light may satisfy a resonance condition in a horizontal direction. When the excitation light emitting element 105 satisfies the resonance condition in the horizontal direction, the light to be emitted in the wavelength converter 32 direction decreases. Thus, the amount of excitation light to be absorbed by the wavelength converter 32 decreases, and the amount of long wavelength light to be generated also decreases. Note that the side surfaces 16iS are preferably tilted in an opened manner toward the wavelength converter 32. Excitation light can be efficiently transmitted to the wavelength converter 32. As will be described below, a tilt angle θe of the side surface 16iS is preferably smaller than 90 degrees and larger than or equal to 63 degrees.

In the configuration illustrated in FIG. 11, the first partition 34i may have insulating properties or electrical conductivity. Furthermore, the first partition 34i may have transparency or light blocking properties with respect to excitation light or long wavelength light. However, when the excitation light emitting element 105 does not have the reflective film 18, the first partition 34i needs to have light blocking properties. This is because light leakage into adjacent pixels is to be prevented. In addition, as for the light blocking properties here, light blocking caused by reflection is preferable to light blocking caused by absorption. Thus, light is returned to the excitation light emitting element 105, which makes it possible to suppress a reduction in luminous efficiency of excitation light.

The P electrode 23P is a reflective surface disposed proximate to the second surface, and a metal material having high reflectivity such as silver, aluminum or the like is disposed on a surface proximate to the main body 16i. The reflective surface is in contact with at least a surface of the P-side layer 13 proximate to the second surface and preferably covers the second surface of the main body 16i as wide as possible. This is because the light leakage toward the driving circuit substrate 50 is reduced and the light emission efficiency is improved. Note that in this configuration, the reflective surface disposed proximate to the second surface is formed of metal in order to be used as both the reflective surface and the P electrode, but the P electrode 23P may be formed of a transparent conductive film, and a dielectric multilayer film may be disposed below the transparent conductive film. In such a case, the reflective surface is formed of the dielectric multilayer film.

The N electrode 30 may be a transparent conductive film, for example, may be an oxide semiconductor such as Indium-Tin-Oxide (ITO), Indium-Zinc-Oxide (IZO) or the like, or may be a silver nanofiber film or the like. To reduce absorption of light, the N electrode 30 is preferably as thin as possible. When the first partition 34i or a second partition 37 is formed of a conductive material, a wiring line resistance at an N-side can be reduced by using the first partition 34i or the second partition 37 as a part of a wiring line at the N-side. Both the first partition 34i and the second partition 37 may be formed of a conductive material and may be used as the wiring line at the N-side.

The wavelength converter 32 is disposed on the upper surface of the N electrode 30. The wavelength converter 32 downconverts excitation light emitted by the nitride semiconductor layer 14N into long wavelength light (emission light). A material forming the wavelength converter 32 preferably does not have light scattering properties, and is a material obtained by dispersing nanoparticles such as quantum dots or quantum rods, or a wavelength conversion material such as a dye in resin, a material obtained by solidifying a wavelength conversion material itself, or the like. The wavelength converter 32 is partitioned for each pixel by using the second partition 37. The second partition 37 can be formed in advance, and the wavelength converter 32 can be formed by printing techniques such as ink jet printing, screen printing or the like. Alternatively, the wavelength converter 32 may be formed in advance by dispersing the wavelength conversion material in a material being in a positive resist state or a negative resist state and performing patterning by a photolithography technique, and then, the second partition 37 may be formed. In the latter case, a process of filling a space between the second partition 37 and the wavelength converter 32 with transparent resin or the like is required.

Concaves and convexes are formed on side surfaces (concave-convex reflective surfaces) of the second partition 37. The concaves and convexes can prevent long wavelength light traveling in the horizontal direction from resonating even when reflection of the long wavelength light is repeated between the second partitions 37 facing each other. Thus, the resonance of the long wavelength light in the horizontal direction can be prevented, and the resonance of the long wavelength light in a vertical direction can be strengthened. As a result, radiation in a forward direction can be strengthened. In a case where there is no concave and convex, a case where a distance between the second partitions 37 facing each other satisfies the resonance conditions easily occurs. For example, when the distance between the second partitions 37 facing each other is set to 2 μm, a refractive index of the wavelength converter 32 is 1.6, and a wavelength of the long wavelength light in vacuum is 530 nm, the resonance conditions occur at intervals of 165.6 nm. Thus, even in a case where the distance between the second partitions 37 facing each other is set so as not to satisfy the resonance conditions, since the distances between the second partitions 37 facing each other are distributed in a range of 2 μm±200 nm when the distance varies in a range of about ±10%, pixels that satisfy the resonance conditions are inevitably appeared. An attempt to avoid the resonance conditions results in reduction of the manufacturing yield and increase in the cost. Note that the sizes of the concaves and convexes are sizes with which long wavelength light can be scattered, and are preferably larger than or equal to a half wavelength of the long wavelength light in the wavelength converter 32. For example, in the example described above, since the wavelength of the long wavelength light in the wavelength converter 32 is 331 nm, a planar interval of the concaves and convexes is preferably equal to or larger than 166 nm.

The side surface of the second partition 37 preferably has high reflectivity for long wavelength light, and is preferably formed of a metal material such as aluminum, silver or the like. As a result, leakage of long wavelength light from the wavelength converter 32 to adjacent pixels can be reduced, and contrast and color purity can be enhanced. When the long wavelength light is red light, gold may be used. The concave-convex shape may be formed by roughening the side surface by etching after formation of the aforementioned metal pattern, or may be formed by forming a resist pattern including particles having a diameter of hundreds of nm, exposing the particles on the side surface to form the concaves and convexes, and then, depositing a thin film of the metal.

The heights of the upper surface of the second partition 37 and the upper surface of the wavelength converter 32 are preferably substantially equal. As a result, formation of the reflection/transmission film 39 can be facilitated. When there is a difference in height between both of the upper surfaces, a transparent resin layer may be disposed so as to flatten the surface.

The reflection/transmission film 39 is a dielectric multilayer film, and exhibits a constant transmittance for vertically incident long wavelength light, but has a property of reflecting light having a large incident angle. A film having a large refractive index for long wavelength light (for example, a titanium oxide film, a silicon nitride film, a niobium oxide film, or the like) and a film having a small refractive index (such as a silicon oxide film) are alternately layered. Note that in FIG. 11, the reflection/transmission film 39 is illustrated as a continuous film across the pixels, but the reflection/transmission film 39 may be divided for each pixel.

A distance in the vertical direction between the reflective surface (second electrode) and the reflection/transmission film 39 is set such that resonance occurs when the long wavelength light reciprocates in the vertical direction. That is, the distance in the vertical direction is set such that, of long wavelength light A incident on the reflection/transmission film 39, long wavelength light B that is reflected at the reflection/transmission film 39, is further reflected by the second electrode, and then is incident on the reflection/transmission film 39 again interferes with the original long wavelength light A so as to intensify with each other.

To prevent leakage of excitation light, the reflection/transmission film 39 needs to be set to have high reflectivity for excitation light. It is preferable that the distance between the reflection/transmission film 39 and the reflective surface (second electrode) do not satisfy resonance conditions for excitation light. The reflection/transmission film 39 needs to be set to have a low transmittance for excitation light, but since it is difficult for a dielectric multilayer film to have a transmittance of 0% in all directions, when the resonance conditions are satisfied, the excitation light may be emitted in a specific direction, which is not preferable as the characteristics of the image display element 200i. In a case where it is not possible to sufficiently reduce the leakage of the excitation light by only the reflection/transmission film 39, a color filter layer that absorbs the excitation light may be disposed proximate to the light emitting surface of the reflection/transmission film 39.

The shape and dimensions of the wavelength converter 32 in a plan view are preferably substantially equal to the shape and dimensions of the excitation light emitting surface 130 of the excitation light emitting element 105 in a plan view, and the wavelength converter 32 preferably overlaps the excitation light emitting surface 130 in a plan view. Here, the excitation light emitting surface 130 is a surface that emits the excitation light from the excitation light emitting element 105 to the wavelength converter 32, and when the N electrode 30 is thin, the excitation light emitting surface 130 is the upper surface of the N electrode 30 on the main body 16i and the protection film 17. Furthermore, the shape and dimensions of the wavelength converter 32 in a plan view are related to a surface on which convexes and concaves are averaged. In a plan view, when a part of the wavelength converter 32 does not cover the excitation light emitting surface 130, at such a part of the wavelength converter 32, long wavelength light is reflected between the first partition 34i and the reflection/transmission film 39, does not satisfy the resonance conditions, and results in little contribution to the forward radiation. Conversely, when a part of the excitation light emitting surface 130 is not covered by the wavelength converter 32 in a plan view, at such a part of the excitation light emitting surface 130, the excitation light is absorbed or reflected by the second partition 37, and cannot be incident on the wavelength converter 32. Thus, part of the excitation light is wasted. In a plan view, the wavelength converter 32 and the excitation light emitting surface 130 preferably have the identical shape and the identical dimensions so as to overlap each other with accuracy of dimensional control and overlap control in the manufacturing process. In a pattern having convexes and concaves, as for the accuracy described above, a dimensional control accuracy of ±20% and an overlap control accuracy of ±0.3 μm can be achieved.

An area of the P electrode 23P in a plan view is preferably as wide as possible in order to define a region in which long wavelength light can resonate. As illustrated in FIG. 11, when the side surfaces 16iS are tilted in an opened manner with respect to the light emission direction, the shape of the P electrode 23P in a plan view is substantially identical to that of the excitation light emitting surface 130, and the dimensions of the P electrode 23P are not larger than the dimensions of the excitation light emitting surface 130. The difference in dimension between the P electrode 23P and the excitation light emitting surface 130 is determined by the tilt angle of the side surfaces 16iS, and thus, in order to increase the area of the P electrode 23P, it is preferable that the tilt angle θe of the side surface 16iS with respect to the surface of the driving circuit substrate 50 be close to 90 degrees. However, since the resonance conditions may be satisfied when the tilt angle is 90 degrees, the tilt angle is preferably smaller than 90 degrees and equal to or larger than 63 degrees. When the tilt angle is larger than or equal to 63 degrees, a reduction in dimension of the P electrode 23P in the horizontal direction due to the tilt of the side surfaces 16iS is approximately equal to the thickness of the main body 16i, and the influence of the reduction in area can be suppressed to be smaller than 30%.

In this configuration, even when the lengths of the sides of the wavelength converter 32 in a plan view are not precisely controlled, occurrence of resonance in the horizontal direction of the wavelength converter 32 can be prevented, so that the microcavity effect of the wavelength converter 32 can be uniformly achieved among the pixels. Furthermore, as for the excitation light emitting element 105, since occurrence of resonance in the horizontal direction can be prevented by tilting the side surfaces 16iS, intensity variations in excitation light incident on the wavelength converter 32 among the pixels can be reduced. Thus, long wavelength light having narrow wavelength distribution and strongly distributed forward can be uniformly emitted over the entire display element. The yield of the image display elements 200i can be increased and the image display elements 200i can be manufactured at low cost. That is, image display elements having high contrast, high color purity, and low power consumption can be achieved at low cost.

### Eleventh Embodiment

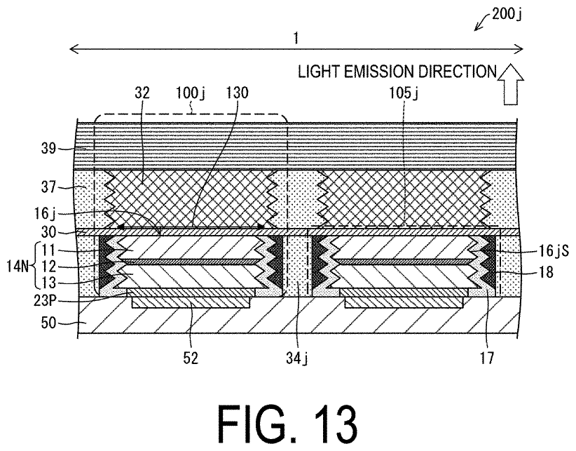

Another embodiment of the present disclosure will be described below with reference to FIG. 13. Note that, for convenience of explanation, components having the identical function to those described in the above-described embodiment will be denoted by the identical reference signs, and descriptions of those components will be omitted.

In an image display element 200j illustrated in a cross-sectional schematic view of FIG. 13, an excitation light emitting element 105j constituting a micro light emitting element 100j differs from the excitation light emitting element 105 of the tenth embodiment. In other respects, there is no difference from the tenth embodiment. Note that in FIG. 13, a cross-sectional view of the connection region 3 is omitted, but the connection region 3 similar to that of the tenth embodiment is also included in the present embodiment.

In the tenth embodiment described above, the side surfaces 16iS are tilted in order for the excitation light emitting element 105 not to satisfy the resonance condition in the horizontal direction. On the other hand, in the image display element 200j according to an eleventh embodiment, a side surface 16jS of a main body 16j of the excitation light emitting element 105j has concaves and convexes. The concaves and convexes of the side surface 16jS can be formed, for example, by processing the nitride semiconductor layer 14N into a single piece, and then performing etching with an alkali solution. The planar sizes of the concaves and convexes are preferably sizes capable of scattering excitation light, and are preferably equal to or larger than a half wavelength of the excitation light in the interior of the main body 16j. For example, when the wavelength of the excitation light in vacuum is 450 nm, the wavelength of the excitation light in the interior of the main body 16j is 182 nm, and thus, a planar interval of the concaves and convexes is preferably equal to or larger than 91 nm.

The present embodiment is similar to the tenth embodiment in that the protection film 17 made of a transparent insulating film and the reflective film 18 are disposed on the side surface 16jS. Additionally, the present embodiment is also similar to the tenth embodiment in that a first partition 34j is disposed between the excitation light emitting elements 105j. The first partition 34j does not need to have a side surface tilted like the first partition 34i according to the tenth embodiment, and a difference between the first partition 34i and the first partition 34j is only a cross-sectional shape.

In this configuration as well, even when the lengths of the sides of the excitation light emitting element 105 in a plan view are not precisely controlled, it is possible to prevent occurrence of resonance of excitation light in a horizontal direction in the excitation light emitting element 105j. As a result, variations in excitation light to be emitted to the wavelength converter 32 among the pixels can be reduced. Thus, variations in the amount of the excitation light to be absorbed by the wavelength converter 32 among the pixels can be reduced. The wavelength converter 32, as in the tenth embodiment, enables the microcavity effect for long wavelength light to be uniformly achieved among the pixels. Thus, long wavelength light having narrow wavelength distribution and strongly distributed forward can be uniformly emitted over the entire display element. A yield of the image display elements 200j can be increased and the image display elements 200j can be manufactured at low cost.

### Twelfth Embodiment

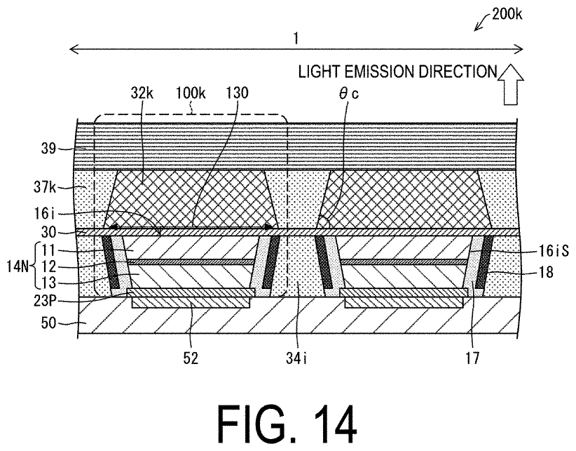

Another embodiment of the present disclosure will be described below with reference to FIG. 14. Note that, for convenience of explanation, components having the identical function to those described in the above-described embodiment will be denoted by the identical reference signs, and descriptions of those components will be omitted.

In the tenth and eleventh embodiments described above, in order to prevent resonance of long wavelength light in the horizontal direction in the wavelength converter 32, the concaves and convexes are provided on the side walls of the wavelength converter 32. In contrast, in an image display element 200k according to a twelfth embodiment, tilted surfaces are used. In other respects, there is no difference from the tenth embodiment. Note that in FIG. 14, a cross-sectional view of the connection region 3 is omitted, but the connection region 3 similar to that of the tenth embodiment is also included in the present embodiment.

As illustrated in FIG. 14, side surfaces (tilted reflective surfaces) of second partitions 37k of a micro light emitting element 100k are tilted in a closed manner toward a light emission direction. A tilt angle θc of the side surface of the second partition 37k with respect to the surface of the driving circuit substrate 50 may be smaller than 90 degrees. By tilting the side walls of the wavelength converter 32k, occurrence of resonance of long wavelength light in a horizontal direction is prevented. Furthermore, long wavelength light and excitation light can be confined in the interior of a cavity by tilting the side walls in a closed manner toward the light emission direction. By confining the excitation light in the interior of the cavity, the amount of the excitation light to be absorbed by the wavelength converter 32k can be increased. Furthermore, by confining the long wavelength light in the interior of the cavity, a microcavity effect can be further enhanced. Thus, the generation of pixels satisfying the resonance conditions in the horizontal direction due to dimensional variations in the wavelength converter 32k is prevented, and the light emission intensity of the long wavelength light can be increased.

The lower surface of the wavelength converter 32k preferably covers the excitation light emitting surface 130 of the excitation light emitting element 105. The excitation light can be taken into the wavelength converter 32k without waste. On the other hand, when the lower surface of the wavelength converter 32k is significantly larger than the excitation light emitting surface 130, long wavelength light is reflected at the upper surface of the first partition 34i, and loss of the long wavelength light occurs. Thus, the lower surface of the wavelength converter 32k preferably matches the excitation light emitting surface 130 of the excitation light emitting element 105 with accuracy that can be achieved in the manufacturing process.

It is only required that the tilt angle θc be smaller than 90 degrees, but when the tilt angle is significantly small, a volume of a part of the wavelength converter 32k below the side wall of the second partition 37k is increased. Since the microcavity effect does not work on this part, it is not preferable that the volume of the part of the wavelength converter 32k below the side wall of the second partition 37k be increased. The volume of the part of the wavelength converter 32k below the side wall of the second partition 37k is preferably smaller than or equal to a half of the total volume of the wavelength converter 32k.

According to the present embodiment, similar effects to those of the tenth embodiment can be also achieved.

Note that in FIG. 14, a case is illustrated in which the tilt angle θc of the side wall of the second partition 37k is smaller than 90 degrees, but even when the tilt angle θc is larger than 90 degrees, occurrence of resonance in the horizontal direction can be prevented. Thus, when the tilt angle θc is not 90 degrees, similar effects to those in the tenth embodiment can be achieved. Further, when the tilt angle θc is larger than 90 degrees, light extraction efficiency can be improved by causing, of long wavelength light generated by the wavelength converter 32, long wavelength light traveling in the horizontal direction to be reflected upward and to be incident on the reflection/transmission film 39.

### Thirteenth Embodiment

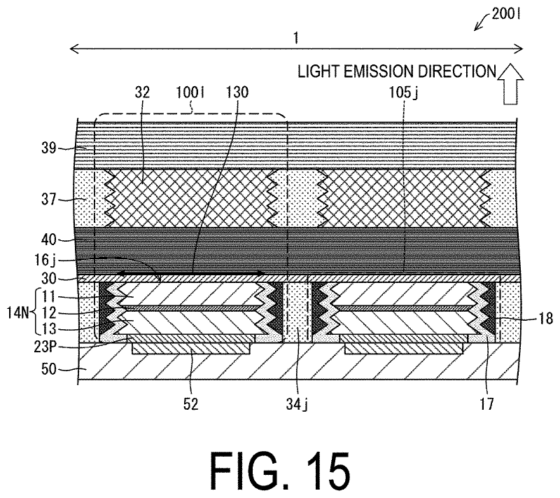

Another embodiment of the present disclosure will be described below with reference to FIG. 15. Note that, for convenience of explanation, components having the identical function to those described in the above-described embodiment will be denoted by the identical reference signs, and descriptions of those components will be omitted.

In the tenth to twelfth embodiments described above, the reflective film proximate to the lower surface constituting the microcavity is disposed proximate to the lower surface of the excitation light emitting elements 105 and 105j. On the other hand, in a micro light emitting element 100l of an image display element 200l according to a thirteenth embodiment, a long wavelength light reflective film 40 is provided between the excitation light emitting element 105j and the wavelength converter 32. The other points are similar to those in the other embodiments. In FIG. 15, the wavelength converter 32, the second partition 37, and the reflection/transmission film 39 are similar to those in the tenth embodiment, and the excitation light emitting element 105j is similar to that in the eleventh embodiment. Note that in FIG. 15, a cross-sectional view of the connection region 3 is omitted, but the connection region 3 similar to that in the tenth embodiment is also included in the present embodiment.

As illustrated in FIG. 15, the long wavelength light reflective film 40 is provided between the excitation light emitting element 105j and the wavelength converter 32. The long wavelength light reflective film 40 is a dielectric multilayer film, and has a function of a band pass filter that is designed to reflect long wavelength light and to transmit excitation light therethrough. For long wavelength light, the long wavelength light reflective film 40 has higher reflectivity than that of the reflection/transmission film 39. A distance in a vertical direction between the long wavelength light reflective film 40 and the reflection/transmission film 39 is set such that long wavelength light resonates when reciprocating in the vertical direction. That is, the distance in the vertical direction is set such that, of long wavelength light A incident on the reflection/transmission film 39, long wavelength light B that is reflected at the reflection/transmission film 39, is further reflected at the long wavelength light reflective film 40, and then is incident on the reflection/transmission film 39 again interferes with the original long wavelength light A so as to intensify with each other. Note that in FIG. 15, the long wavelength light reflective film 40 is disposed as a film continuous across the pixels, but may be divided for each pixel.

In this configuration, both the wavelength converter 32 and the excitation light emitting element 105j have a structure that prevents resonance in a horizontal direction, so that similar effects to those in the tenth to twelfth embodiments can be achieved. Furthermore, a microcavity structure can be achieved by controlling the thickness of the wavelength converter 32. In the tenth to twelfth embodiments, since the microcavity structure includes both the wavelength converter 32 and the excitation light emitting element 105j, the thickness of the wavelength converter 32 needs to be set according to the optical thickness of the excitation light emitting element 105j, which requires complicated control in manufacturing. However, in this configuration, the microcavity structure is formed only by the thickness control of the wavelength converter 32, so that the control is simple in manufacturing.

According to the present embodiment, similar effects to those of the tenth embodiment can be also achieved.

### Fourteenth Embodiment

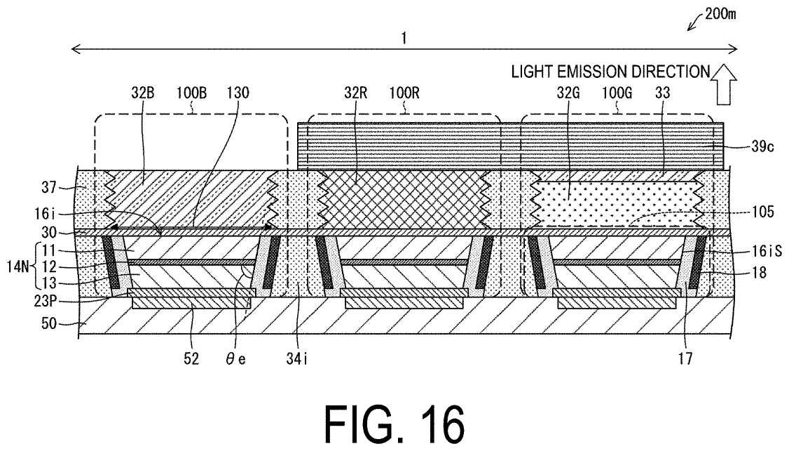

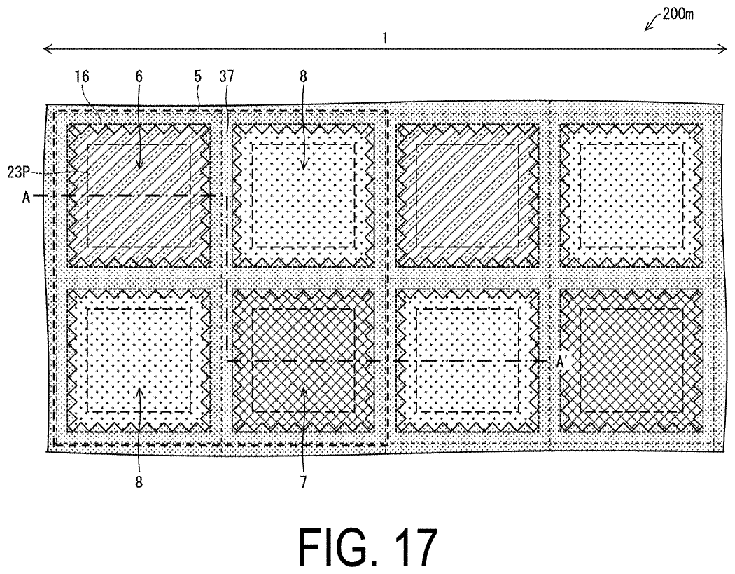

Another embodiment of the present disclosure will be described below with reference to FIG. 16 and FIG. 17. Note that, for convenience of explanation, components having the identical function to those described in the above-described embodiment will be denoted by the identical reference signs, and descriptions of those components will be omitted.

The first to thirteenth embodiments described above is directed to a monochrome display element, but a target of an image display element 200m according to a fourteenth embodiment is a full color display element. FIG. 16 is a cross-sectional schematic view of the full color image display element 200m, and FIG. 17 is a schematic plan view thereof.

As illustrated in FIG. 17, the pixels 5 are arranged in an array in the pixel region 1, and each of the pixels 5 include a blue subpixel 6, a red subpixel 7, and a green subpixel 8. The respective subpixels emit blue light, red light, and green light, and the respective intensities are adjusted, allowing the pixel 5 to emit light of various colors. In this configuration, two green subpixels may be provided for one pixel, but the arrangement and number of subpixels in the pixel may have other configurations. FIG. 16 illustrates a cross-sectional view taken along an A-A′ line in FIG. 17.

Each of the blue, red, and green subpixels 6, 7, and 8 includes the excitation light emitting element 105, and excitation light is blue light. The blue subpixel 6 includes a blue micro light emitting element 100B, and the blue micro light emitting element 100B includes the excitation light emitting element 105 and a transparent portion 32B. The red subpixel 7 includes a red micro light emitting element 100R, and the red micro light emitting element 100R includes the excitation light emitting element 105 and a red wavelength converter 32R. Similarly, the green subpixel 8 includes a green micro light emitting element 100G, and the green micro light emitting element 100G includes the excitation light emitting element 105 and a green wavelength converter 32G. In this configuration, a reflection/transmission film 39c is disposed on the upper surfaces of the red subpixel 7 and the green subpixel 8, and is not disposed on the upper surface of the blue subpixel 6. That is, the red subpixel 7 and the green subpixel 8 have a microcavity structure, but the blue subpixel 6 does not have a microcavity structure.

The configuration of the red subpixel 7 is similar to that of the tenth embodiment, and a distance between the reflection/transmission film 39c and the P electrode 23P is set so that the red light is in a resonant state between the reflection/transmission film 39c and the P electrode 23P. Further, the concaves and convexes are formed on the side walls (concave-convex reflective surfaces) of the red wavelength converter 32R, and the long wavelength light is prevented from being in the resonant state in a horizontal direction. By tilting the side walls of the excitation light emitting element 105, the excitation light is prevented from resonating in the horizontal direction in the excitation light emitting element 105. The side walls of the red wavelength converter 32R may be tilted surfaces, similar to those in the twelfth embodiment, and the side walls of the excitation light emitting element 105 may have the concaves and convexes, similar to those in the eleventh embodiment.

The green subpixel 8 is similar to the red subpixel 7, but differs in that a transparent layer 33 is disposed between the green wavelength converter 32G and the reflection/transmission film 39c. In forming a dielectric multilayer film serving as the reflection/transmission film 39c, it is very important to planarize an underlayer on which the film is to be deposited in order to obtain the dielectric multilayer film having good quality. On the other hand, since light emission wavelengths are very different between the red subpixel 7 and the green subpixel 8, it is difficult for red light and green light to achieve resonant states in the red subpixel 7 and the green subpixel 8, respectively, when the wavelength converters have an identical thickness. Thus, the green wavelength converter 32G is made thinner than the red wavelength converter 32R, and the transparent layer 33 having a thickness corresponding to a difference between the thicknesses of both the red wavelength converter 32R and the green wavelength converter 32G is formed. The transparent layer 33 has a refractive index that greatly differs from refractive indices of the red wavelength converter 32R and the green wavelength converter 32G. In other words, by appropriately selecting the thickness of the transparent layer 33, resonant states of red light and green light can be achieved in the red subpixel 7 and the green subpixel 8, respectively, and also the surfaces of the red subpixel 7 and the green subpixel 8 can be flattened to obtain the dielectric multilayer film having high quality.

In this configuration, the transparent layer 33 is provided in the green subpixel 8, but the green wavelength converter 32G may be made thicker to be configured to be in contact with the reflection/transmission film 39c, and the red wavelength converter 32R and the transparent layer 33 may be provided in the red subpixel 7. For example, when an absorption coefficient of the green wavelength converter 32G for excitation light is smaller than an absorption coefficient of the red wavelength converter 32R for excitation light, the green wavelength converter 32G needs to be made thicker. In such a case, the transparent layer 33 is preferably provided in the red subpixel 7.

Since the blue subpixel 6 emits excitation light to the outside through the transparent portion 32B, the blue subpixel 6 relatively strongly distributes light forward. Thus, it is not always necessary to employ a microcavity structure. However, the presence of the transparent portion 32B increases emission efficiency of the excitation light. Furthermore, the transparent portion 32B also serves to protect the excitation light emitting element 105 when the reflection/transmission film 39c of the blue subpixel 6 is removed. Thus, it is preferable that the transparent portion 32B is present.

In this configuration, blue light is used as excitation light, but it is also possible to use near-ultraviolet light or ultraviolet light as excitation light and provide a blue wavelength converter in the blue subpixel 6. In this case, the reflection/transmission film 39c is also disposed on the blue subpixel 6. The reflection/transmission film 39c in this case has high reflectivity for near-ultraviolet light or ultraviolet light serving as the excitation light, and is configured to serve as a reflection/transmission film in a wavelength band from blue light to red light. Furthermore, by adjusting layer thicknesses of the blue wavelength converter, the green wavelength converter, and the red wavelength converter, and the thickness and refractive index of the transparent layer, each of the blue, red, and green subpixels 6, 7, and 8 can employ a microcavity structure.

According to the present embodiment, similar effects to those of the tenth embodiment can be also achieved.

While there have been described what are at present considered to be certain embodiments of the invention, it will be understood that various modifications may be made thereto, and it is intended that the appended claims cover all such modifications as fall within the true spirit and scope of the invention.

1. An image display element comprising:
a plurality of pixels arranged in an array, each of the plurality of pixels including a micro light emitting element; and
a driving circuit substrate including a driving circuit configured to supply a current to the micro light emitting element to cause the micro light emitting element to emit light,
wherein the micro light emitting element emits emission light in an opposite direction to the driving circuit substrate,
the micro light emitting element includes
a light emitting portion configured to generate the emission light,
a reflection/transmission film provided on the light emitting portion at a part facing in a light emission direction, and
a reflective surface provided on the light emitting portion at a part proximate to the driving circuit substrate,
the reflection/transmission film and the reflective surface constitute a microcavity for the emission light, and
a tilted reflective surface is provided on a side of the light emitting portion.

2. An image display element comprising:
a plurality of pixels arranged in an array, each of the plurality of pixels including a micro light emitting element; and
a driving circuit substrate including a driving circuit configured to supply a current to the micro light emitting element to cause the micro light emitting element to emit light,
wherein the micro light emitting element emits emission light in an opposite direction to the driving circuit substrate,
the micro light emitting element includes
a light emitting portion configured to generate the emission light,
a reflection/transmission film provided on the light emitting portion at a part facing in a light emission direction, and
a reflective surface provided on the light emitting portion at a part proximate to the driving circuit substrate,
the reflection/transmission film and the reflective surface constitute a microcavity for the emission light, and
a concave-convex reflective surface is provided on a side of the light emitting portion.

3. The image display element according to claim 1,
wherein the reflection/transmission film is divided for each of the plurality of pixels by a third partition.

4. The image display element according to claim 2,
wherein the reflection/transmission film is divided for each of the plurality of pixels by a third partition.

5. The image display element according to claim 1,
wherein the tilted reflective surface is tilted in an opened manner toward the light emission direction of the light emitting portion.

6. The image display element according to claim 1,
wherein a first partition is provided between each two of the plurality of pixels.

7. The image display element according to claim 1,
wherein the light emitting portion includes a main body formed of a compound semiconductor configured to generate the emission light, and
the tilted reflective surface is a side surface of the main body.

8. The image display element according to claim 6,
wherein the tilted reflective surface is a side surface of the first partition.

9. The image display element according to claim 1,
wherein the tilted reflective surface is tilted in a closed manner toward the light emission direction of the light emitting portion.

10. The image display element according to claim 2,
wherein the light emitting portion includes a main body formed of a compound semiconductor configured to generate the emission light, and
the concave-convex reflective surface is formed by causing a side surface of the main body to include a concave and a convex.

11. The image display element according to claim 1,
wherein the light emitting portion is a wavelength converter configured to convert excitation light generated by an excitation light emitting element to the emission light,
the excitation light emitting element, the wavelength converter, and the reflection/transmission film are layered in this order on the driving circuit substrate, and
a second partition is disposed on a side surface of the wavelength converter.

12. The image display element according to claim 11,
wherein a side wall of the wavelength converter is tilted in a closed manner with respect to the light emission direction.

13. The image display element according to claim 11,
wherein the excitation light emitting element includes a main body formed of a nitride semiconductor layer configured to generate the excitation light, and
the main body is divided for each of the plurality of pixels, and a side wall of the main body includes a concave and a convex.

14. The image display element according to claim 11,
wherein the excitation light emitting element includes a main body formed of a nitride semiconductor layer configured to generate the excitation light, and
the main body is divided for each of the plurality of pixels, and a side wall of the main body is tilted with respect to the light emission direction.

15. The image display element according to claim 11,
wherein an upper surface of the wavelength converter and an upper surface of the second partition constitute a smooth flat surface.

16. The image display element according to claim 11,
wherein a long wavelength reflective film is disposed between the excitation light emitting element and the wavelength converter.

17. The image display element according to claim 2,
wherein the light emitting portion is a wavelength converter configured to convert excitation light generated by an excitation light emitting element to the emission light,
the excitation light emitting element, the wavelength converter, and the reflection/transmission film are layered in this order on the driving circuit substrate, and
a second partition is disposed on a side surface of the wavelength converter.

18. The image display element according to claim 17,
wherein the excitation light emitting element includes a main body formed of a nitride semiconductor layer configured to generate the excitation light, and
the main body is divided for each of the plurality of pixels, and a side wall of the main body includes a concave and a convex.

19. The image display element according to claim 17,
wherein the excitation light emitting element includes a main body formed of a nitride semiconductor layer configured to generate the excitation light,
the main body is divided for each of the plurality of pixels, and a side wall of the main body is tilted with respect to the light emission direction.

20. The image display element according to claim 17,
wherein an emission light reflective film is disposed between the excitation light emitting element and the wavelength converter.
